(19) United States
(12) Patent Application Publication
(10) Pub. No.: US 2024/0427245 A1
(43) Pub. Date: Dec. 26, 2024

(54) PHOTOSENSITIVE RESIN AND PHOTORESIST COMPOSITION CONTAINING THE SAME

(71) Applicant: TAKOMA TECHNOLOGY CO., LTD., Nonsan-si (KR)

(72) Inventors: Mi Sun Ryu, Daejeon (KR); Jin Kyu Park, Sejong-si (KR)

(21) Appl. No.: 18/821,318

(22) Filed: Aug. 30, 2024

Related U.S. Application Data
(63) Continuation of application No. PCT/KR2022/019880, filed on Dec. 8, 2022.

(30) Foreign Application Priority Data
Dec. 7, 2022 (KR) 10-2022-0169693

(51) Int. Cl. G03F 7/075; C07F 7/18; C08F 220/18; C08F 230/08

(52) U.S. Cl. CPC G03F 7/0758; C07F 7/1804; C08F 220/1811; C08F 230/085; G03F 7/0755; C08F 2800/10

(57) ABSTRACT

The present invention relates to a photosensitive resin that has high solubility in and good etching resistance to a developer even under sub-248 nm and 193 nm short-wavelength exposure sources and forms a low line edge roughness. The present invention also relates to a photoresist composition including the photosensitive resin.

### CROSS-REFERENCE TO RELATED APPLICATIONS

This application is a Continuation of Application No. PCT/KR2022/019880, filed on Dec. 8, 2022, which in turn claims the benefit of Korean Patent Application No. 10-2022-0169693, filed on Dec. 7, 2022. The entire disclosures of all these applications are hereby incorporated by reference.

### TECHNICAL FIELD

The present invention relates to a photosensitive resin and a photoresist composition including the same. More specifically, the present invention relates to a photosensitive resin that has high solubility in and good etching resistance to a developer even under sub-248 nm and 193 nm short-wavelength exposure sources and forms a low line edge roughness, and a photoresist composition including the photosensitive resin.

### BACKGROUND ART

With high integration of semiconductor integrated circuit devices, Gbit-class dynamic random access memories (DRAMs) with a higher capacity than existing DRAMs with a memory capacity of 256 megabits have been developed. There is also a demand to develop photosensitive polymer resins and chemically amplified photoresist compositions that can form photoresist patterns with a line width (e.g., 90 nm) narrower than the line width (e.g., 0.25 m) of conventional photoresist patterns.

In general, chemically amplified photoresist compositions are used in photolithographic processes under extreme ultraviolet exposure sources such as KrF and ArF excimer lasers, which are sub-250 nm short-wavelength exposure sources. Such chemically amplified photoresist compositions should meet the following requirements: i) high transparency to exposure light; ii) good adhesion to semiconductor circuit boards; iii) excellent etching resistance; (iv) no damage such as line edge roughness (LER), top loss, and slope to photoresist patterns; and (v) easy development with common developers such as aqueous tetramethylammonium hydroxide (TMAH) solutions.

However, although the use of shorter wavelength light sources such as extreme ultraviolet exposure sources (EUVL, 11-13 nm) and F2 (157 nm) enables the formation of patterns with smaller sizes, these light sources require the use of thin photoresist films due to their high absorbances. Immersion lithography is a process that uses ArF (193 nm) as a light source or water filled in a space between a transmission lens and a wiper. This process has the problem that the miniaturization of a photoresist pattern leads to a reduced adhesion area to a semiconductor circuit board, causing the resist pattern to collapse. In an attempt to solve this problem, the thickness of the photoresist film may be reduced. In this case, however, poor etching resistance is caused.

Thus, bulky compounds are introduced to enhance the etching resistance of thin photoresists. However, photoresist compositions including bulky compounds have reduced solubility in developers despite their improved etching resistance, resulting in high line edge roughness. Etching resistance is the biggest problem of thin photoresists.

Therefore, there is a need for a new type of photoresist that can overcome these disadvantages.

### DETAILED DESCRIPTION OF THE INVENTION

### Problems to be Solved by the Invention

The present invention has been made in view of the above-described problems and is intended to provide a photosensitive resin that has high solubility in and good etching resistance to a developer even under sub-248 nm and 193 nm short-wavelength exposure sources and forms a low line edge roughness, and a photoresist composition including the photosensitive resin.

### Means for Solving the Problems

One aspect of the present invention provides a photosensitive compound having a structure represented by Formula 1 or 2:

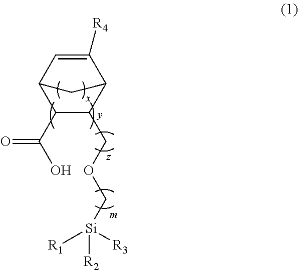

wherein x is 0 or 1, y is an integer from 0 to 3, z is an integer from 1 to 10, m is an integer from 1 to 6, R₁, R₂, and R₃ are each independently a C₁-C₁₀ hydrocarbon or OCₙH₂ₙ₊₁ (n is an integer from 0 to 10), and R₄ is H or CH₃;

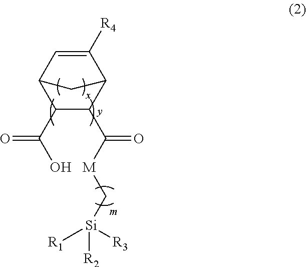

wherein x is 0 or 1, y is an integer from 0 to 3, z is an integer from 1 to 10, M is C, O, N or S, R₁, R₂, and R₃ are each independently a C₁-C₁₀ hydrocarbon or OCₙH₂ₙ₊₁ (n is an integer from 0 to 10), and R₄ is H or CH₃.

In one embodiment, the photosensitive compound may be selected from the group consisting of the compounds represented by Formulas 3 to 34:

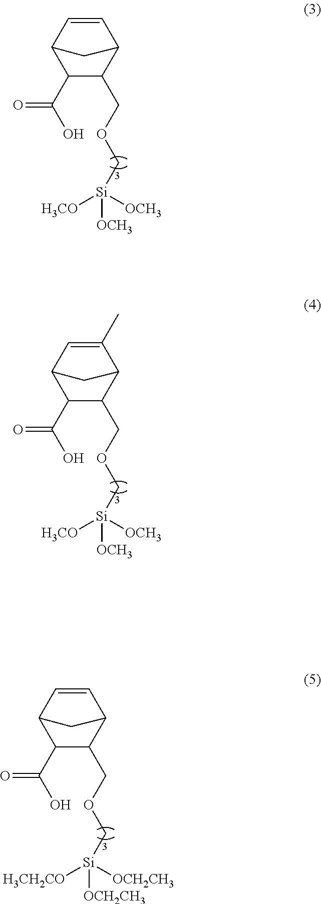

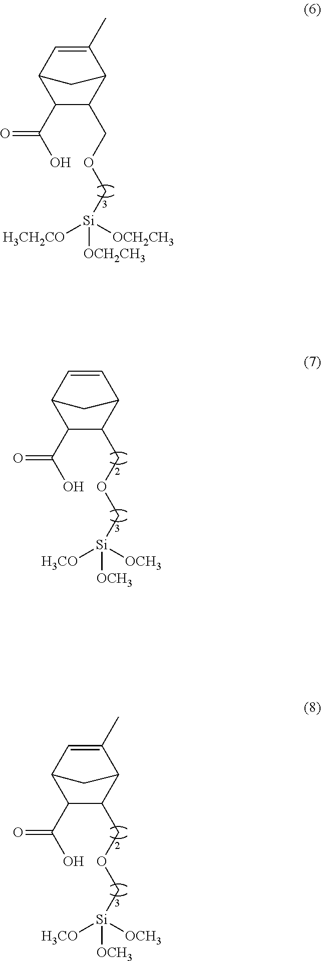

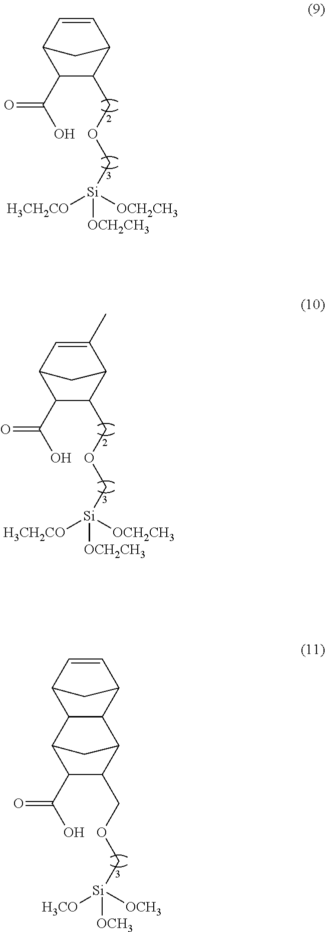

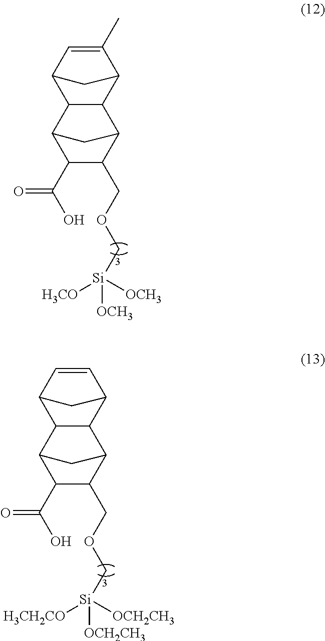

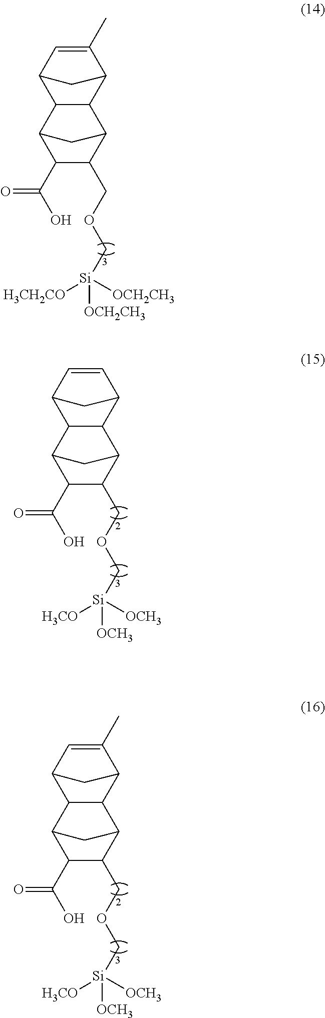

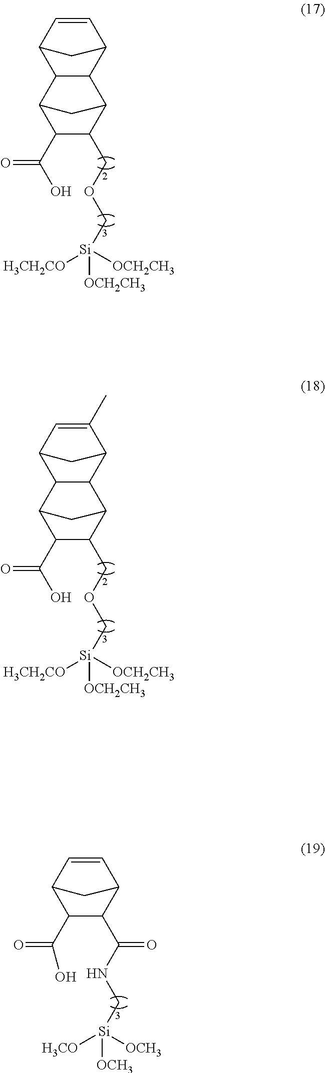

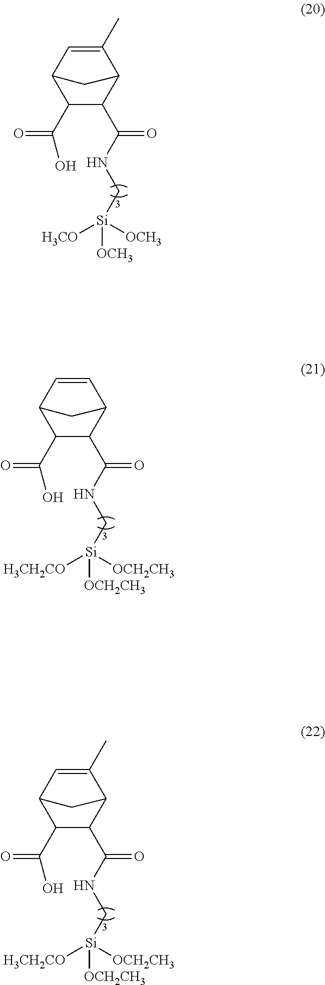

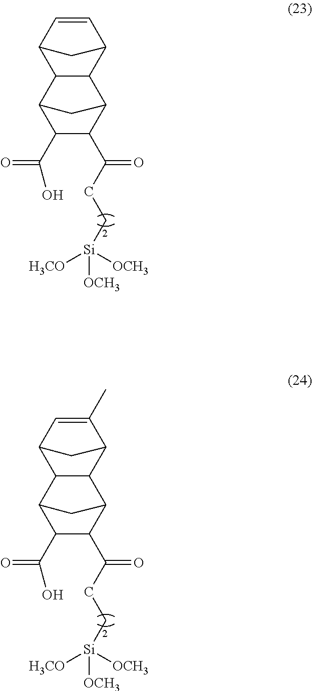

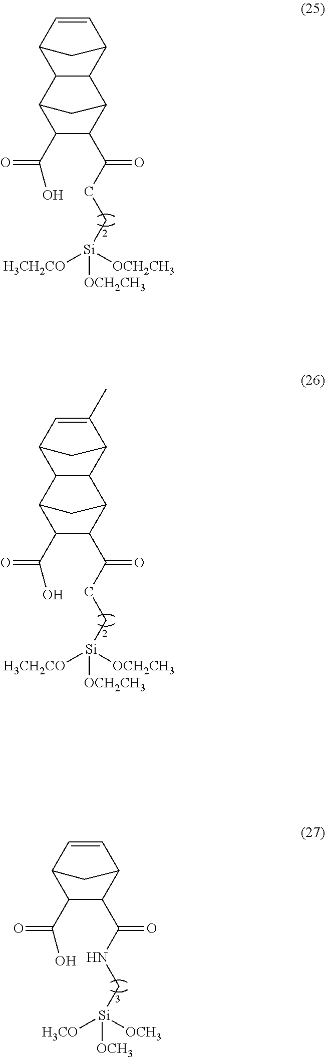

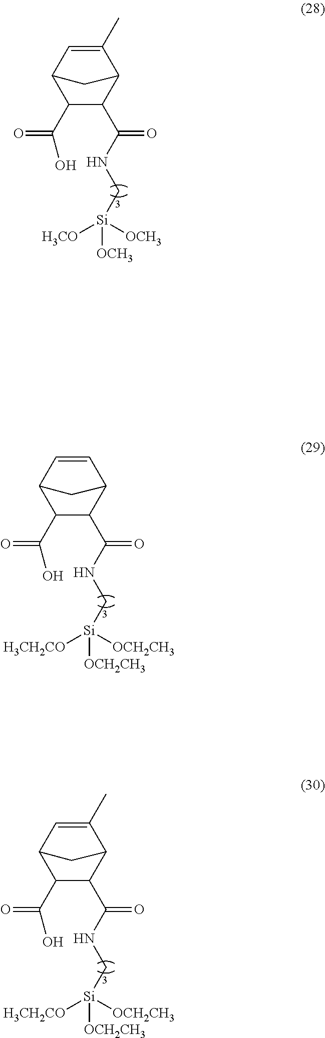

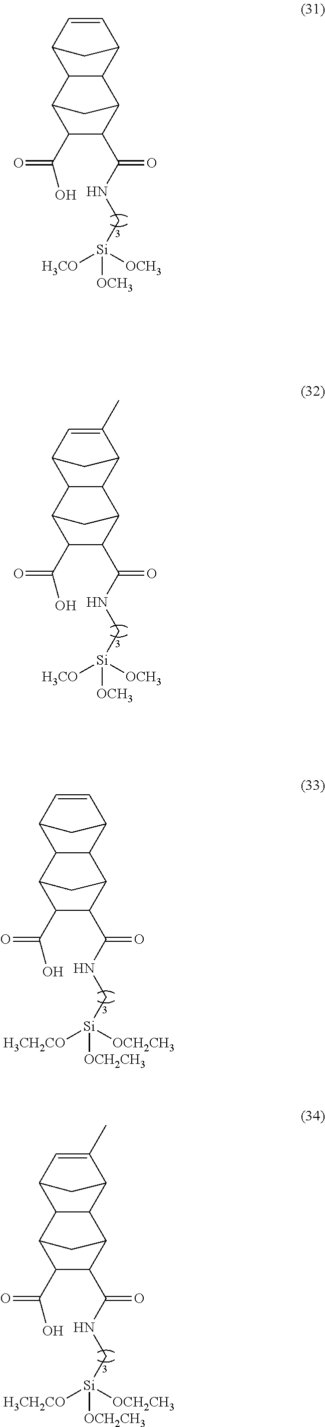

A further aspect of the present invention provides a photosensitive resin having a structure represented by Formula 35 or 36:

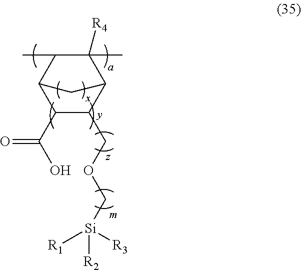

wherein x is 0 or 1, y is an integer from 0 to 3, z is an integer from 1 to 10, m is an integer from 1 to 6, R₁, R₂, and R₃ are each independently a C₁-C₁₀ hydrocarbon or OCₙH₂ₙ₊₁ (n is an integer from 0 to 10), and R₄ is H or CH₃, and a represents the mole fraction of the repeating unit having the structure represented by Formula 35 in all repeating units of the photosensitive resin and is 0.01 to 100 mol %,

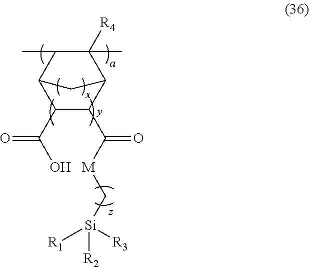

wherein x is 0 or 1, y is an integer from 0 to 3, z is an integer from 1 to 10, M is C, O, N or S, R₁, R₂, and R₃ are each independently a C₁-C₁₀ hydrocarbon or OCₙH₂ₙ₊₁ (n is an integer from 0 to 10), and R₄ is H or CH₃, and a represents the mole fraction of the repeating unit having the structure represented by Formula 36 in all repeating units of the photosensitive resin and is 0.01 to 100 mol %.

In one embodiment, the photosensitive resin may include a structure represented by Formula 37 or 38:

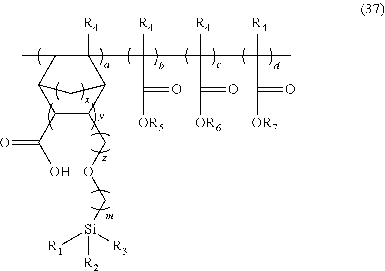

wherein each R₄ is independently H or a C₁-C₆ alkyl group, R₁, R₂, and R₃ are each independently a C₁-C₁₀ hydrocarbon or OCₙH₂ₙ₊₁ (n is an integer from 1 to 10), R₅ is a C₁-C₂₀ alkyl group or a C₅-C₄₀ cycloalkyl group, R₆ and R₇ are each independently a C₁-C₂₀ hydroxyalkyl group, a C₁-C₁₀ halogenated hydroxyalkyl group or a C₅-C₁₀ cycloalkyl group containing an ether or ester moiety, and a, b, c, and d represent the mole fractions of the corresponding repeating units in all photosensitive compounds of the photosensitive polymer resin and are in a ratio of 1-70:1-50:1-50:1-50;

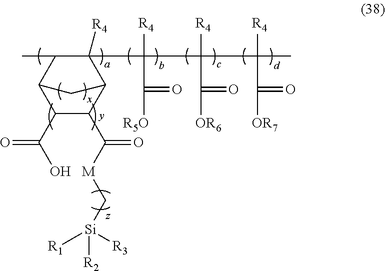

wherein R₁, R₂, R₃, R₄, R₅, R₆, R₇, a, b, c, and d are as defined in Formula 37.

In one embodiment, a may be 1 to 70 mol %.

In one embodiment, the photosensitive resin may have a weight average molecular weight of 1,000 to 100,000.

Another aspect of the present invention provides a photoresist composition including a photosensitive resin having a structure represented by Formula 35 or 36, a photoacid generator, and an organic solvent:

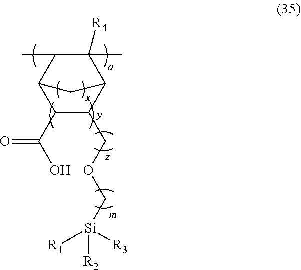

wherein x is 0 or 1, y is an integer from 0 to 3, z is an integer from 1 to 10, m is an integer from 1 to 6, R₁, R₂, and R₃ are each independently a C₁-C₁₀ hydrocarbon or OCₙH₂ₙ₊₁ (n is an integer from 0 to 10), and R₄ is H or CH₃, and a represents the mole fraction of the repeating unit having the structure represented by Formula 35 in all repeating units of the photosensitive resin and is 0.01 to 100 mol %,

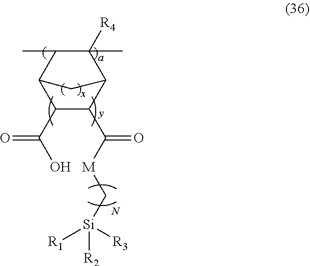

wherein x is 0 or 1, y is an integer from 0 to 3, z is an integer from 1 to 10, M is C, O, N or S, R₁, R₂, and R₃ are each independently a C₁-C₁₀ hydrocarbon or OCₙH₂ₙ₊₁ (n is an integer from 0 to 10), and R₄ is H or CH₃, and a represents the mole fraction of the repeating unit having the structure represented by Formula 36 in all repeating units of the photosensitive resin and is 0.01 to 100 mol %.

In one embodiment, the photosensitive resin may be present in an amount of 1 to 30% by weight, based on the total weight of the photoresist composition.

In one embodiment, the photoacid generator may be selected from organic sulfonic acids, sulfide salt compounds, onium salt compounds, and mixtures thereof and may be present in an amount of 0.1 to 20 parts by weight, based on 100 parts by weight of the photosensitive resin.

In one embodiment, the organic solvent may be selected from the group consisting of ethylene glycol monomethyl ethyl, ethylene glycol monoethyl ether, ethylene glycol monomethyl ether, diethylene glycol monoethyl ether, propylene glycol monomethyl ether acetate, toluene, xylene, methyl ethyl ketone, cyclohexanone, 2-hydroxyethyl propionate, 2-hydroxy-2-methyl ethyl propionate, ethoxyethyl acetate, hydroxyethyl acetate, 2-hydroxy-3-methyl methyl butanoate, 3-methoxy-2-methyl methyl propionate, 3-ethoxyethyl propionate, 3-methoxy-2-methyl ethyl propionate, ethyl acetate, butyl acetate, and mixtures thereof.

### Effects of the Invention

The presence of silicon in the photosensitive resin of the present invention and the introduction of norbornene moieties, which are bulky alicyclic hydrocarbons, into the photosensitive resin of the present invention lead to enhanced etching resistance and heat resistance and improved adhesion to a semiconductor circuit board.

The photosensitive resin of the present invention has a structure in which organic acid groups are present in silicon-containing norbornene moieties, which are bulky alicyclic hydrocarbons. This structure facilitates control over the solubility of the photosensitive resin and increases the contrast due to the difference in solubility, leading to a low line edge roughness (LER).

In addition, the photosensitive resin and photoresist composition of the present invention have better etching resistance to oxides and polysilicon than conventional resist compositions.

### MODE FOR CARRYING OUT THE INVENTION

Preferred embodiments of the present invention will now be described in detail. In the description of the present invention, detailed explanations of related art are omitted when it is deemed that they may unnecessarily obscure the essence of the present invention. Throughout the specification, the singular forms “a”, “an” and “the” are intended to include the plural forms as well, unless the context clearly indicates otherwise. It is to be understood that the terms such as “including” or “having,” etc., are intended to indicate the existence of the features, numbers, steps, operations, components, parts, or combinations thereof disclosed in the specification, and are not intended to preclude the possibility that one or more other features, numbers, steps, operations, components, parts, or combinations thereof may exist or may be added. Respective steps of the methods described herein may be performed in a different order than that which is explicitly described. In other words, the respective steps may be performed in the same order as described, substantially simultaneously, or in a reverse order.

The present invention is not limited to the illustrated embodiments and may be embodied in various different forms. Rather, the disclosed embodiments are provided so that this disclosure will be thorough and complete, and will fully convey the scope of the invention to those skilled in the art. In the drawings, the dimensions, such as widths and thicknesses, of elements may be exaggerated for clarity. The drawings are explained from an observer's point of view. It will be understood that when an element is referred to as being “on” another element, it can be directly on the other element, or one or more intervening elements may also be present therebetween. It will be understood by those skilled in the art that various changes in form and details may be made therein without departing from the spirit and scope of the invention as defined by the appended claims. The same reference numerals represent substantially the same elements throughout the drawings.

As used herein, the term “and/or” encompasses both combinations of the plurality of related items disclosed and any item from among the plurality of related items disclosed. In the present specification, the description “A or B” means “A”, “B”, or “A and B.” The present invention is directed to a photosensitive compound having a structure represented by Formula 1 or 2:

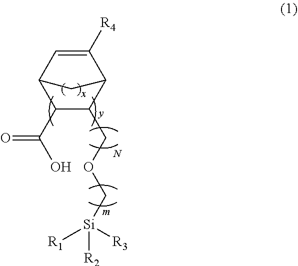

wherein x is 0 or 1, y is an integer from 0 to 3, z is an integer from 1 to 10, m is an integer from 1 to 6, R₁, R₂, and R₃ are each independently a C₁-C₁₀ hydrocarbon or OCₙH₂ₙ₊₁ (n is an integer from 0 to 10), and R₄ is H or CH₃;

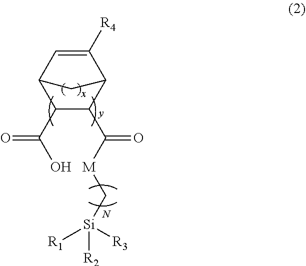

wherein x is 0 or 1, y is an integer from 0 to 3, z is an integer from 1 to 10, M is C, O, N or S, R₁, R₂, and R₃ are each independently a C₁-C₁₀ hydrocarbon or OCₙH₂ₙ₊₁ (n is an integer from 0 to 10), and R₄ is H or CH₃.

In Formula 1 or 2, x may be 0 or 1. When x is 0, it means the absence of a hydrocarbon structure connecting the center of the cyclohexane moiety in Formula 1 or 2. When x is 1, it means the presence of a hydrocarbon structure crossing the cyclohexane.

In Formula 1 or 2, y indicates repeated formation of the cyclohexane moiety. When y is 0, it means that carbonyl groups at one or both sides are connected to the backbone without a cyclohexane moiety.

When x is 1, y may be 1 or 2. In this case, the photosensitive compound has a structure in which one or two cyclohexane moieties are connected to each other and each cyclohexane moiety may include the bridge structure represented by x.

In Formula 1, z corresponds to a structure connecting the cyclohexane moiety and the ether bond and is a C₁-C₁₀ hydrocarbon, preferably a C₁-C₆ hydrocarbon, more preferably a C₁-C₂ hydrocarbon. The hydrocarbon may be a saturated or unsaturated aliphatic one containing C and H only. Some or all of the hydrogen atoms in the hydrocarbon may be substituted with other atoms or other hydrocarbons. If z is 0, poor structural stability may be caused, deteriorating the overall stability of the compound. Meanwhile, if z in Formula 1 exceeds 10, the excessively long structure may cause poor heat resistance.

In Formula 1, m corresponds to a portion connected to the Si-containing terminal structure and may be a C₁-C₆ hydrocarbon. That is, m is 1 to 6, preferably 2 or 3, most preferably 3. If m is 0, the compound may be unstable. Meanwhile, if m exceeds 6, poor heat resistance may be caused.

In Formula 2, z corresponds to a portion connecting the atom represented by M and the Si-containing terminal structure and may be a C₁-C₁₀ hydrocarbon. That is, z in Formula 2 is 1 to 10, preferably 2 or 3, most preferably 3. If z in Formula 2 is 0, poor structural stability may be caused, deteriorating the overall stability of the compound. Meanwhile, if z in Formula 2 exceeds 10, the excessively long structure may cause poor heat resistance.

The Si moiety in Formula 1 or 2 increases the thermal stability of the photosensitive compound according to the present invention and is introduced to form a line edge roughness. The Si moiety may be derived from a compound having a Si atom as a central atom, such as maleic acid. R₁, R₂, and R₃ are each independently a C₁-C₁₀ hydrocarbon or OCₙH₂ₙ₊₁ (n is an integer from 1 to 10). R₁, R₂, and R₃ are each independently preferably OCₙH₂ₙ₊₁ (n is an integer from 1 to 10), more preferably OCₙH₂ₙ₊₁ (n is 1 or 2).

The structure of Formula 1 or Formula 2 is specifically represented by Formulas 3 to 34. That is, the photosensitive compound may include one or more of the compounds represented by Formulas 3 to 34:

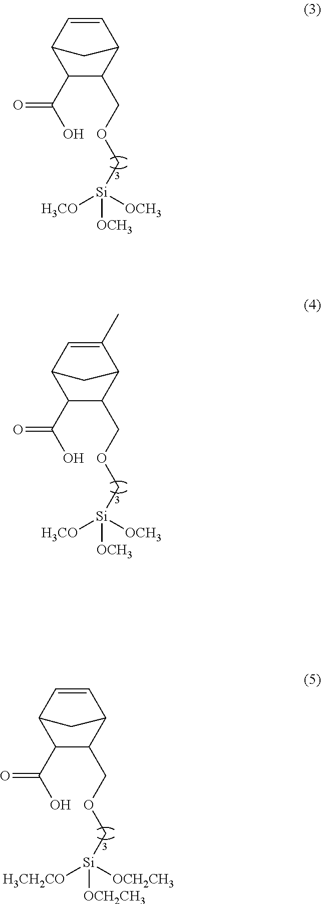

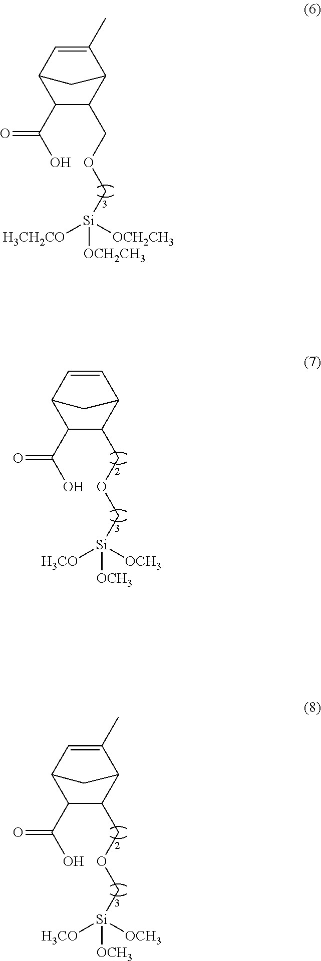

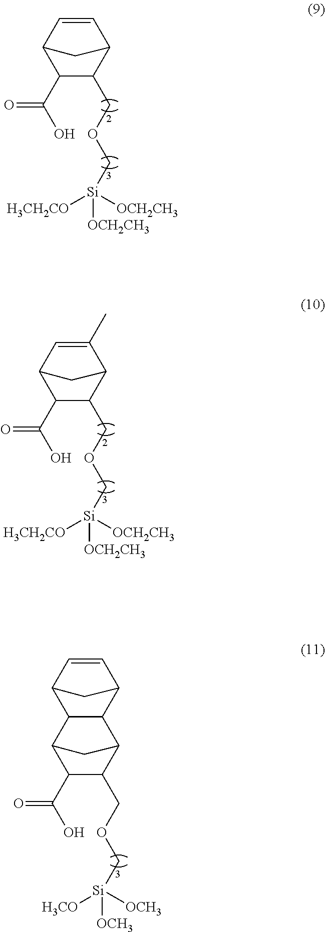

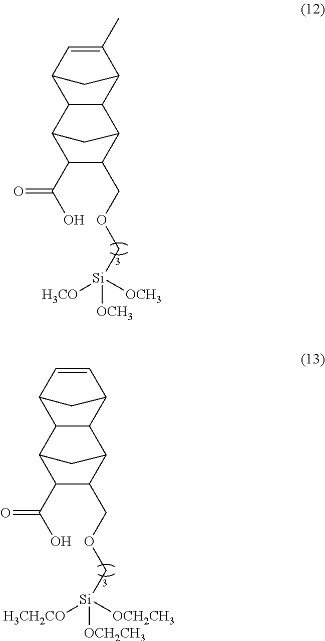

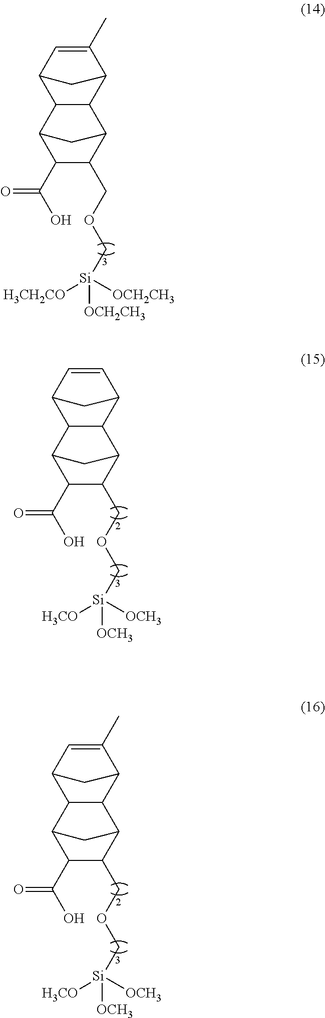

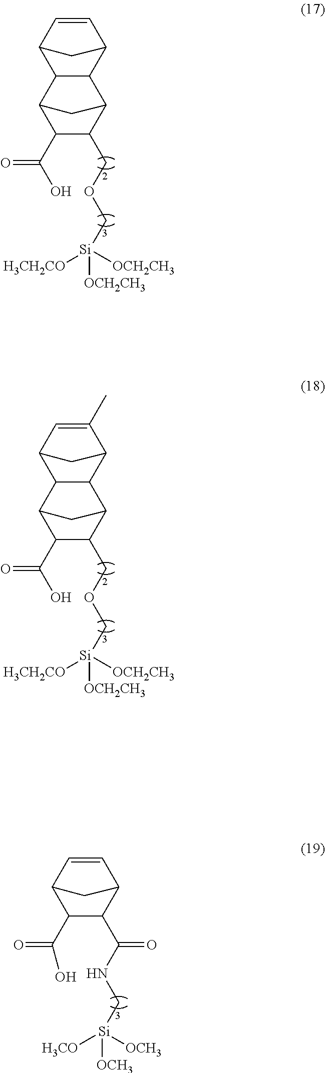

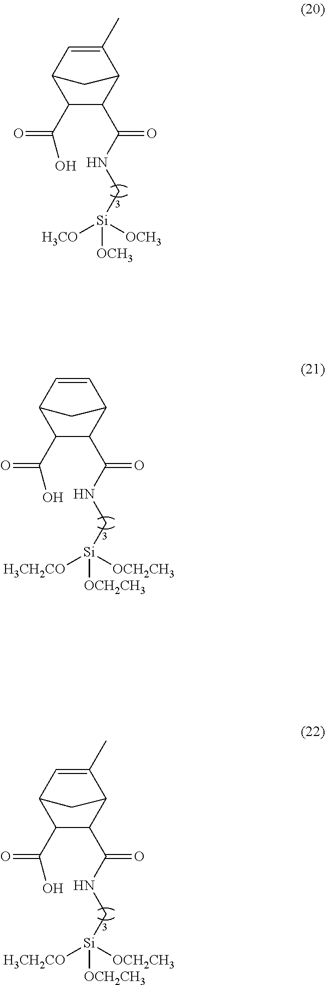

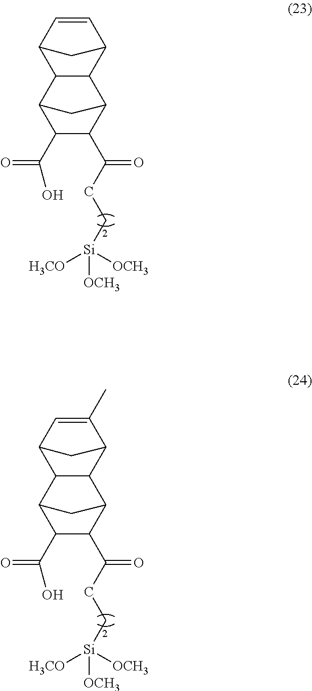

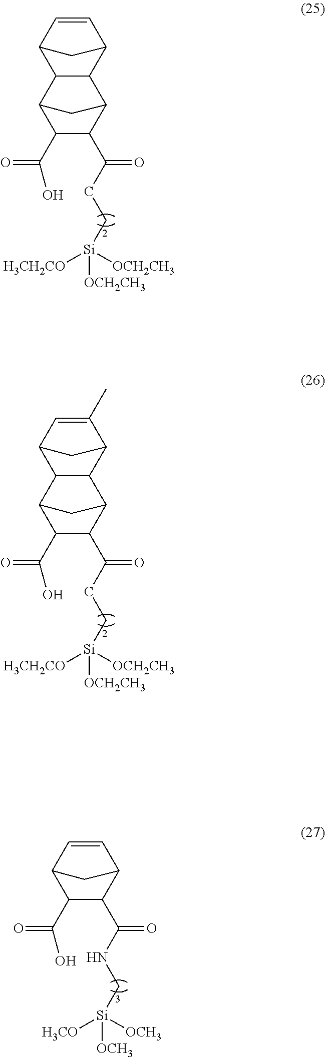

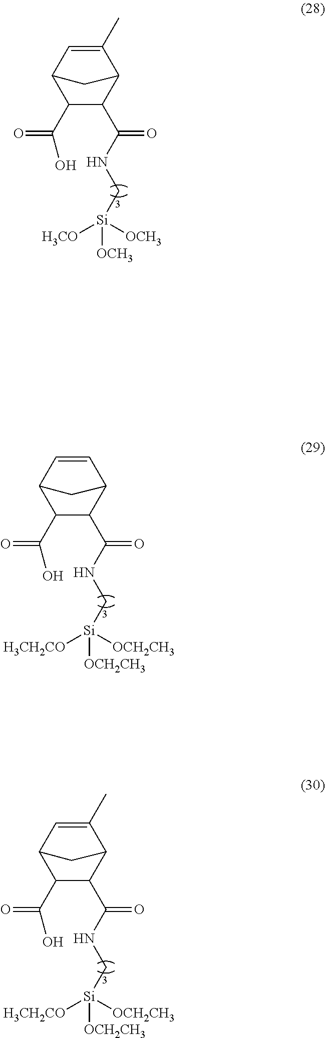

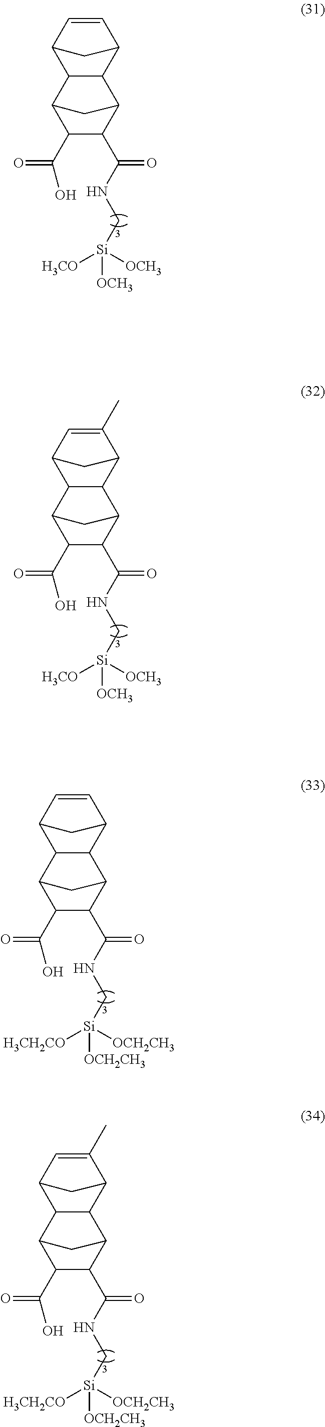

The photosensitive compounds represented by Formulas 1 and 2 can be prepared by a general method for preparing organic compounds. The photosensitive compound represented by Formula 1 is preferably the photosensitive compound represented by Formula 3, which can be synthesized as depicted in Reaction Scheme 1:

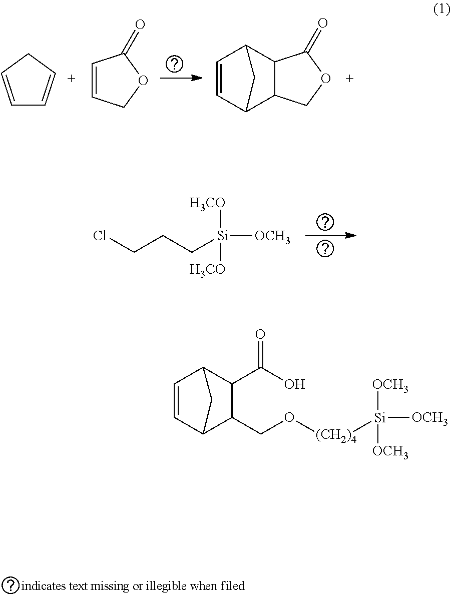

First, a norbornene-lactone compound is prepared by a Diels-Alder reaction between cyclopentadiene and anhydrous furanone. Then, the norbornene compound is esterified with a reagent such as water, alcohol or thiol and chloropropyltrimethoxysilane under acidic or basic conditions to prepare the photosensitive compound represented by Formula 3. The photosensitive compounds represented by Formulas 4 to 18 can be prepared in the same manner as described above for the photosensitive compound represented by Formula 3.

The photosensitive compound represented by Formula 2 is preferably the photosensitive compound represented by Formula 19, which can be synthesized as depicted in Reaction Scheme 2:

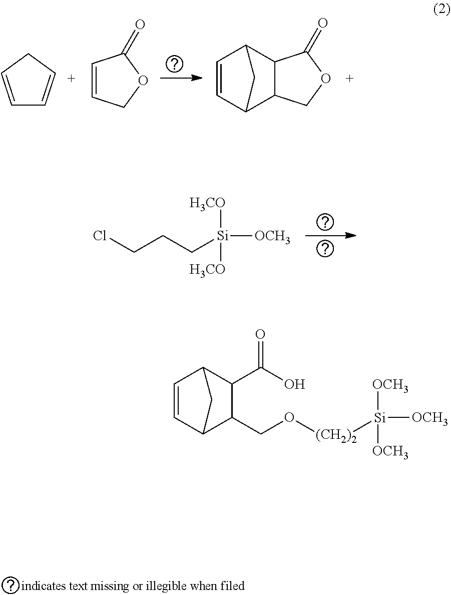

First, a norbornene compound is prepared by a Diels-Alder reaction between cyclopentadiene and maleic anhydride. Then, the norbornene compound is esterified with a reagent such as water, alcohol or thiol and chloropropyltrimethoxysilane under acidic or basic conditions to prepare the photosensitive compound represented by Formula 19. The photosensitive compounds represented by Formulas 20 to 34 can be prepared in the same manner as described above for the photosensitive compound represented by Formula 19.

The as-synthesized photosensitive compound may be used in admixture with a photoresist compound but is preferably polymerized into a polymer resin before use.

Accordingly, a further aspect of the present invention is directed to a photosensitive resin having a structure represented by Formula 35 or 36:

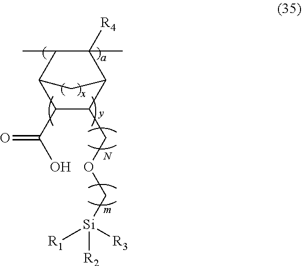

wherein x is 0 or 1, y is an integer from 0 to 3, z is an integer from 1 to 10, m is an integer from 1 to 6, R₁, R₂, and R₃ are each independently a C₁-C₁₀ hydrocarbon or OCₙH₂ₙ₊₁ (n is an integer from 0 to 10), and R₄ is H or CH₃, and a represents the mole fraction of the repeating unit having the structure represented by Formula 35 in all repeating units of the photosensitive resin and is 0.01 to 100 mol %,

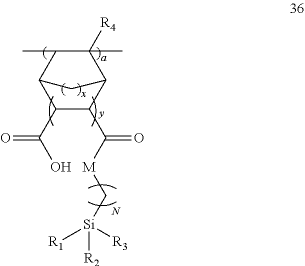

wherein x is 0 or 1, y is an integer from 0 to 3, z is an integer from 1 to 10, M is C, O, N or S, R₁, R₂, and R₃ are each independently a C₁-C₁₀ hydrocarbon or OCₙH₂ₙ₊₁ (n is an integer from 0 to 10), and R₄ is H or CH₃, and a represents the mole fraction of the repeating unit having the structure represented by Formula 36 in all repeating units of the photosensitive resin and is 0.01 to 100 mol %.

Descriptions related to x, y, z, m, and M are the same as those described above for the photosensitive compound and thus will be omitted.

a in Formula 35 or 36 represents the mole fraction of the repeating units having the structure represented by Formula 35 or 36 in all repeating units of the photosensitive resin, specifically the fraction of the number of moles of the repeating unit of Formula 35 or 36 per 100 moles of all repeating units of the photosensitive resin. That is, a in Formula 35 or 36 represents the mol % of the repeating unit of Formula 35 or 36 in all repeating units of the photosensitive resin.

a in Formula 35 or 36 is preferably 0.01 to 100 mol %, more preferably 1 to 70 mol %. If a in Formula 35 or 36 is less than 0.01 mol %, the effects of the present invention may not be obtained. Meanwhile, if a in Formula 35 or 36 is 100 mol %, it means that the photosensitive resin is composed of only the repeating unit of Formula 35 or 36.

The photosensitive resins of Formulas 35 and 36 can be prepared by polymerizing the compounds having the structures of Formulas 1 and 2, respectively. That is, the photosensitive resin of Formula 35 or 36 may include, as repeating units, one or more of the monomers having the structures of Formulas 3 to 34.

The photosensitive resin may have a weight average molecular weight of 1,000 to 100,000 and a degree of dispersion of 1.0 to 5.0. If the weight average molecular weight of the photosensitive resin is lower than 1,000, it may be difficult to expect good etching resistance, which is the main effect of the present invention. Meanwhile, if the weight average molecular weight of the photosensitive resin exceeds 100,000, the viscosity of the photosensitive resin may increase, making it difficult to use the photosensitive resin for a photoresist. If the viscosity of the photosensitive resin is outside the range defined above, there is a risk that the physical properties of a photoresist film formed using the photosensitive resin may be deteriorated or the formation of the photoresist film may be difficult and the contrast of a pattern of the photoresist film may be deteriorated.

The repeating units constituting the photosensitive resins of Formulas 35 and 36 other than the repeating units represented by Formulas 1 and 2 are preferably ones having acid-sensitive protecting groups. Such an acid-sensitive protecting group refers to a dissolution inhibiting group that is bonded to the side chain of the photosensitive resin and can be released by an acid. The acid-sensitive protecting group may inhibit dissolution of a photoresist composition in an alkaline developer in an unexposed portion. In contrast, the acid-sensitive protecting group is deprotected by the catalysis of an acid generated from a photoacid generator in an exposed portion to increase the solubility of a photoresist composition in a general alkaline developer, resulting in a large solubility difference in the exposed and unexposed portions. The photoacid generator will be described later.

That is, attachment of acid-sensitive protecting groups to a photoresist material inhibits dissolution of the photoresist material in an alkaline developer but release of acid-sensitive protecting groups by an acid generated from a photoacid generator when stimulated by light allows a photoresist material to be dissolved in a developer.

The acid-sensitive protecting group is not limited as long as it can perform the above roles. The acid-sensitive protecting group is preferably t-butyl, tetrahydropyran-2-yl, 2-methyltetrahydropyran-2-yl, tetrahydrofuran-2-yl, 2-methyltetrahydrofuran-2-yl, 1-methoxypropyl, 1-methoxy-1-methylethyl, 1-ethoxypropyl, 1-ethoxy-1-methylethyl, 1-methoxyethyl, 1-ethoxyethyl, t-butoxyethyl, 1-isobutoxyethyl or 2-acetylmenth-1-yl.

The structure of the photosensitive resins can be represented by Formula 37 or 38:

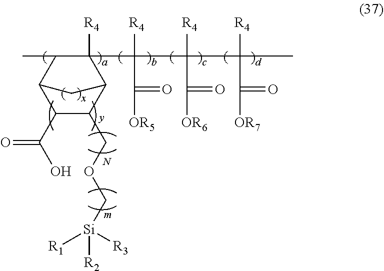

wherein each R₄ is independently H or a C₁-C₆ alkyl group, R₁, R₂, and R₃ are each independently a C₁-C₁₀ hydrocarbon or OCₙH₂ₙ₊₁ (n is an integer from 1 to 10), R₅ is a C₁-C₂₀ alkyl group or a C₅-C₄₀ cycloalkyl group, R₆ and R₇ are each independently a C₁-C₂₀ hydroxyalkyl group, a C₁-C₁₀ halogenated hydroxyalkyl group or a C₅-C₁₀ cycloalkyl group containing an ether or ester moiety, and a, b, c, and d represent the mole fractions of the corresponding repeating units in all photosensitive compounds of the photosensitive polymer resin and are in a ratio of 1-70:1-50:1-50:1-50;

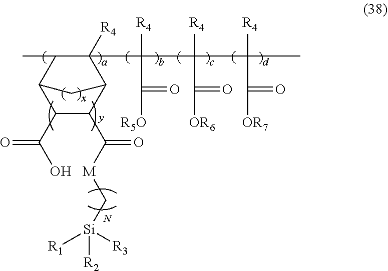

wherein R₁, R₂, R₃, R₄, R₅, R₆, R₇, a, b, c, and d are as defined in Formula 37.

The presence of silicon in the photosensitive resin of the present invention and the introduction of norbornene moieties, which are bulky alicyclic hydrocarbons, into the photosensitive resin of the present invention lead to enhanced etching resistance and heat resistance and improved adhesion to a semiconductor circuit board. The photosensitive resin of the present invention has a structure in which organic acid groups are present in silicon-containing norbornene moieties, which are bulky alicyclic hydrocarbons. This structure facilitates control over the solubility of the photosensitive resin and increases the contrast due to the difference in solubility, leading to a low line edge roughness (LER).

The photosensitive resin of the present invention can be prepared by a method including i) dissolving the photosensitive compounds represented by Formulas 1 and 2 and the photosensitive compounds represented by R₅, R₆, and R₇ in Formulas 37 and 38 in a polymerization solvent, ii) adding an initiator to the mixture solution, and iii) allowing the mixture solution containing the initiator to react at a temperature of 60° C. to 70° C. for 4 to 48 hours under a nitrogen or argon atmosphere. The polymerization is preferably carried out by radical polymerization, solution polymerization, bulk polymerization or ionic polymerization using a metal catalyst. The method may further include purifying the reaction product of step iii) by crystallization from diethyl ether, hexane, petroleum ether, alcohol such as methanol, ethanol or isopropanol, water, or a mixture thereof.

The polymerization solvent may be selected from a wide variety of polymerization solvents commonly known in the art. Non-limiting examples of such polymerization solvents include cyclohexanone, cyclopentanone, tetrahydrofuran, dimethylformamide, dimethyl sulfoxide, dioxane, methyl ethyl ketone, benzene, toluene, and xylene. These polymerization solvents may be used alone or as a mixture thereof. The polymerization initiator may be selected from a wide variety of polymerization initiators commonly known in the art. Non-limiting examples of such polymerization initiators include benzoyl peroxide, 2,2′-azobisisobutyronitrile, acetyl peroxide, lauryl peroxide, t-butyl peracetate, t-butyl hydroperoxide, and di-t-butyl peroxide. These polymerization initiators may be used alone or as a mixture thereof.

A photoresist composition of the present invention includes the photosensitive resin having the structure represented by Formula 35 or 36, a photoacid generator (PAG) generating an acid, and an organic solvent. The photoresist composition of the present invention may optionally further include various types of additives.

The photosensitive resin is the same as that described above. The photosensitive resin may be present in an amount of 1 to 30% by weight, based on the total weight of the photoresist composition. If the photosensitive resin is present in an amount of less than 1% by weight, it may be difficult to form a pattern using the photoresist composition. Meanwhile, if the photosensitive resin is present in an amount exceeding 30% by weight, the viscosity of the photoresist composition may increase, making it difficult to form an appropriate pattern.

The photoacid generator generates an acid component such as H⁺ to induce chemical amplification when exposed to light. The photoacid generator may be any compound that can generate an acid by light. The photoacid generator is preferably a sulfide salt compound such as an organic sulfonic acid, an onium salt compound such as an onium salt, or a mixture thereof. Non-limiting examples of suitable photoacid generators include phthalimide trifluoromethane sulfonate, dinitrobenzyl tosylate, n-decyl disulfone, naphthylimidotrifluoromethane sulfonate, diphenyliodonium hexafluorophosphate, diphenyliodonium hexafluoroarsenate, diphenyliodonium hexafluoroantimonate, diphenyl-p-methoxyphenylsulfonium triflate, diphenyl-p-toluenylsulfonium triflate, diphenyl-p-isobutylphenylsulfonium triflate, triphenylsulfonium hexafluoroarsenate, triphenylsulfonium hexafluoroantimonate, triphenylsulfonium triflate, and dibutylnaphthylsulfonium triflate, which have low absorbances at 157 nm and 193 nm. These photoacid generators may be used alone or as a mixture thereof. The content of the photoacid generator is preferably 0.1 to 20 parts by weight, based on 100 parts by weight of the photosensitive resin. If the content of the photoacid generator is less than 0.1 parts by weight, the sensitivity of the photoresist composition to light may be lowered, making it difficult to deprotect the protecting groups. Meanwhile, if the content of the photoacid generator exceeds 20 parts by weight, a large amount of an acid may be generated from the photoacid generator, resulting in the formation of a photoresist pattern whose cross section is damaged.

The organic solvent makes up the remainder of the photoresist composition according to the present invention. The organic solvent may be selected from a wide variety of organic solvents commonly used in the preparation of photoresist compositions. Non-limiting examples of such organic solvents include ethylene glycol monomethyl ethyl, ethylene glycol monoethyl ether, ethylene glycol monomethyl ether, diethylene glycol monoethyl ether, propylene glycol monomethyl ether acetate (PGMEA), toluene, xylene, methyl ethyl ketone, cyclohexanone, 2-hydroxyethyl propionate, 2-hydroxy-2-methyl ethyl propionate, ethoxyethyl acetate, hydroxyethyl acetate, 2-hydroxy-3-methyl methyl butanoate, 3-methoxy-2-methyl methyl propionate, 3-ethoxyethyl propionate, 3-methoxy-2-methyl ethyl propionate, ethyl acetate, and butyl acetate. These organic solvents may be used alone or as a mixture thereof.

The photoresist composition of the present invention may optionally further include an organic base. Non-limiting examples of such organic bases include triethylamine, triisobutylamine, triisooctylamine, diethanolamine, and triethanolamine. These organic bases may be used alone or as a mixture thereof. The content of the organic base is preferably 0.01 to 10% by weight, based on the total weight of the photoresist composition. If the content of the organic base is less than 0.01% by weight, there is a risk that a so-called t-top phenomenon may occur in a photoresist pattern formed using the photoresist composition. Meanwhile, if the content of the organic base exceeds 10% by weight, the sensitivity of the photoresist composition may be reduced, posing a risk of poor processability and productivity.

The chemically amplified photoresist composition of the present invention includes is a blend of the photosensitive resin, the photoacid generator, the organic solvent, and optionally various types of additives. The chemically amplified photoresist composition of the present invention is preferably prepared such that its solids content is 1 to 30% by weight, based on the total weight of the photoresist composition. The chemically amplified photoresist composition of the present invention is filtered through a 0.2 m filter before use if desired.

The photoresist composition of the present invention can be used to form a thin photoresist film and a pattern by the following procedure.

First, i) the photoresist composition of the present invention is applied to the surface of a layer to be etched, such as a silicon wafer or an aluminum substrate, using a spin coater to form a thin film and ii) the thin film is exposed to a short-wavelength light source. Then, iii) the exposed photoresist film is heated as needed and iv) the heated resist film is developed to form a photoresist pattern.

The method for forming a photoresist pattern may further include prebaking the resist film by heating after the application step i) and prior to the exposure step ii). The prebaking step and step iii) of heating the exposed photoresist are preferably carried out at 70° C. to 200° C. If the heating temperature is lower than 70° C., the organic solvent present in the photoresist composition may not be sufficiently evaporated. Meanwhile, if the heating temperature exceeds 200° C., the photoresist composition may be thermally decomposed.

A developer used in the development step iv) may be any of those commonly known in the art. The developer is preferably an alkaline developer, more preferably an aqueous tetramethylammonium hydroxide (TMAH) solution. The concentration of the developer is preferably 0.1 to 10% by weight. Appropriate amounts of a water-soluble organic solvent such as methanol or ethanol and a surfactant may be added to the developer.

Preferred embodiments of the present invention will be described in detail with reference to the accompanying drawings such that those skilled in the art can readily practice the invention. In describing the present invention, detailed explanations of a related known function or construction are omitted when it is deemed that they may unnecessarily obscure the essence of the invention. Certain features shown in the drawings are enlarged, reduced or simplified for ease of illustration and the drawings and the elements thereof are not necessarily in proper proportion. However, those skilled in the art will readily understand such details.

### Example 1

### Preparation of Photosensitive Compound (Formula 3)

### 1) Preparation of Norbornene-Lactone Compound

As depicted in Reaction Scheme 1, 130 g of cyclopentadiene was added dropwise to a reactor containing the same equivalent of anhydrous furanone and 1 L of benzene. The mixture was subjected to a Diels-Alder reaction with stirring. The reactor was cooled in a dry ice bath. After completion of the dropwise addition, the temperature of the reaction mixture was allowed to rise to room temperature. The reaction was carried out with stirring at room temperature for 24 h to obtain a norbornene-lactone compound (yield 88%). [H-NMR (CDCl3): δ (ppm), 6.23 (CH, 2H), 3.77 (CH, 1H), 2.58 (CH, 1H), 1.75 (CH2, 2H), 2.31 (CH, 1H), 2.11 (CH, 1H), 4.38 (CH2, 2H)]

### 2) Preparation of Photosensitive Compound (Formula 3)

As depicted in Reaction Scheme 1, 0.3 mol (45.05 g) of the norbornene-lactone compound obtained in Example 1 and 0.32 mol (46.79 g) of triethylamine were dissolved in 200 ml of THF and 0.32 mol (63.59 g) of 3-chloropropyltrimethoxysilane was added dropwise thereto. The reaction was allowed to proceed at room temperature. After completion of the reaction, THF was removed by distillation under reduced pressure. The reaction mixture was added with water, neutralized with dilute hydrochloric acid, extracted with ethyl acetate, dried over anhydrous MgSO4, and purified by column chromatography to afford the photosensitive compound represented by Formula 3 (yield 73%). [H-NMR (CDCl3): δ (ppm), 6.23 (CH, 2H), 3.46 (CH, 1H), 2.58 (CH, 1H), 1.75 (CH2, 2H), 2.40 (CH, 1H), 2.18 (CH, 1H), 3.46 (CH2, 2H), 2.66 (CH2, 6H), 3.55 (CH3, 9H), 11.0 (OH, 1H)]

### Examples 2-16

The photosensitive compounds represented by Formulas 4-18 were synthesized in the same manner as in Example 1. The structures of the photosensitive compounds were confirmed via H-NMR. The results are shown in Table 1. The yields of the photosensitive compounds are also shown in Table 1.

TABLE 1

| Example No. | Formula | H-NMR data (CDCl3: δ (ppm)) | Yield (%) |
|---|---|---|---|
| Example 2 | Formula 4 | 5.38 (CH, 1H), 1.82 (CH3, 3H), 3.46 (CH, 1H), 2.26 | 71 |
| | | (CH, 1H), 1.75 (CH2, 2H), 2.40 (CH, 1H), 2.18 (CH, | |
| | | 1H), 3.46 (CH2, 2H), 2.66 (CH2, 6H), 3.55 (CH3, 9H), | |
| | | 11.0 (OH, 1H) | |
| Example 3 | Formula 5 | 6.23 (CH, 2H), 3.46 (CH, 1H), 2.58 (CH, 1H), 1.75 | 75 |
| | | (CH2, 2H), 2.40 (CH, 1H), 2.18 (CH, 1H), 3.46 (CH2, | |
| | | 2H), 2.66 (CH2, 6H), 3.83 (CH2, 6H), 1.21 (CH3, 9H), | |
| | | 11.0 (OH, 1H) | |
| Example 4 | Formula 6 | 5.38 (CH, 1H), 1.82 (CH3, 3H), 3.46 (CH, 1H), 2.26 | 70 |
| | | (CH, 1H), 1.75 (CH2, 2H), 2.40 (CH, 1H), 2.18 | |
| | | (CH, 1H), 3.46 (CH2, 2H), 2.66 (CH2, 6H), 3.83 (CH2, | |
| | | 6H), 1.21 (CH3, 9H), 11.0 (OH, 1H) | |
| Example 5 | Formula 7 | 6.23 (CH, 2H), 3.46 (CH, 1H), 2.58 (CH, 1H), 1.75 | 71 |
| | | (CH2, 2H), 2.40 (CH, 1H), 2.18 (CH, 1H), 3.46 (CH2, | |
| | | 4H), 2.66 (CH2, 6H), 3.55 (CH3, 9H), 11.0 (OH, 1H) | |
| Example 6 | Formula 8 | 5.38 (CH, 1H), 1.82 (CH3, 3H), 3.46 (CH, 1H), 2.26 | 77 |
| | | (CH, 1H), 1.75 (CH2, 2H), 2.40 (CH, 1H), 2.18 | |
| | | (CH, 1H), 3.46 (CH2, 4H), 2.66 (CH2, 6H), 3.55 (CH3, | |
| | | 9H), 11.0 (OH, 1H) | |
| Example 7 | Formula 9 | 6.23 (CH, 2H), 3.46 (CH, 1H), 2.58 (CH, 1H), 1.75 | 79 |
| | | (CH2, 2H), 2.40 (CH, 1H), 2.18 (CH, 1H), 3.46 (CH2, | |
| | | 4H), 2.66 (CH2, 6H), 3.83 (CH2, 6H), 1.21 (CH3, 9H), | |
| | | 11.0 (OH, 1H) | |
| Example 8 | Formula 10 | 5.38 (CH, 1H), 1.82 (CH3, 3H), 3.46 (CH, 1H), 2.26 | 75 |
| | | (CH, 1H), 1.75 (CH2, 2H), 2.40 (CH, 1H), 2.18 | |
| | | (CH, 1H), 3.46 (CH2, 4H), 2.66 (CH2, 6H), 3.83 (CH2, | |
| | | 6H), 1.21 (CH3, 9H), 11.0 (OH, 1H) | |
| Example 9 | Formula 11 | 6.23 (CH, 2H), 2.58 (CH, 2H), 0.94 (CH2, 2H), 1.44 | 72 |
| | | (CH, 2H), 1.75 (CH, 1H), 1.42 (CH, 1H), 2.13 (CH2, | |
| | | 2H), 2.29 (CH, 1H), 2.07 (CH, 1H), 3.46 (CH2, 2H), | |
| | | 2.66 (CH2, 6H), 3.55 (CH3, 9H), 11.0 (OH, 1H) | |
| Example 10 | Formula 12 | 5.38 (CH, 1H), 1.82 (CH3, 3H), 2.58 (CH, 1H), 2.26 | 70 |
| | | (CH, 1H), 1.75 (CH2, 2H), 1.44 (CH, 2H), 1.75 (CH, | |
| | | 1H), 1.42 (CH, 1H), 2.13 (CH2, 2H), 2.29 (CH, 1H), | |
| | | 2.07 (CH, 1H), 3.46 (CH2, 2H), 2.66 (CH2, 6H), 3.55 | |
| | | (CH3, 9H), 11.0 (OH, 1H) | |
| Example 11 | Formula 13 | 6.23 (CH, 2H), 2.58 (CH, 2H), 0.94 (CH2, 2H), 1.44 | 68 |
| | | (CH, 2H), 1.75 (CH, 1H), 1.42 (CH, 1H), 2.13 (CH2, | |
| | | 2H), 2.29 (CH, 1H), 2.07 (CH, 1H), 3.46 (CH2, 2H), | |
| | | 2.66 (CH2, 6H), 3.83 (CH2, 6H), 1.21 (CH3, 9H), 11.0 | |
| | | (OH, 1H) | |
| Example 12 | Formula 14 | 5.38 (CH, 1H), 1.82 (CH3, 3H), 2.58 (CH, 1H), 2.26 | 66 |
| | | (CH, 1H), 1.75 (CH2, 2H), 1.44 (CH, 2H), 1.75 (CH, | |
| | | 1H), 1.42 (CH, 1H), 2.13 (CH2, 2H), 2.29 (CH, 1H), | |
| | | 2.07 (CH, 1H), 3.46 (CH2, 2H), 2.66 (CH2, 6H), 3.83 | |
| | | (CH2, 6H), 1.21 (CH3, 9H), 11.0 (OH, 1H) | |
| Example 13 | Formula 15 | 6.23 (CH, 2H), 2.56 (CH, 1H), 2.58 (CH, 1H), 0.94 | 70 |
| | | (CH2, 2H), 1.44 (CH, 2H), 1.75 (CH, 1H), 1.42 (CH, | |
| | | 1H), 2.13 (CH2, 2H), 2.29 (CH, 1H), 2.07 (CH, 1H), | |
| | | 3.46 (CH2, 4H), 2.66 (CH2, 6H), 3.55 (CH3, 9H), 11.0 | |
| | | (OH, 1H) | |
| Example 14 | Formula 16 | 5.38 (CH, 1H), 1.82 (CH3, 3H), 2.58 (CH, 1H), 2.26 | 73 |
| | | (CH, 1H), 1.75 (CH2, 2H), 1.44 (CH, 2H), 1.75 (CH, | |
| | | 1H), 1.42 (CH, 1H) 2.13 (CH2, 2H), 2.29 (CH, 1H), 2.07 | |
| | | (CH, 1H), 3.46 (CH2, 4H), 2.66 (CH2, 6H), 3.55 (CH3, | |
| | | 9H), 11.0 (OH, 1H) | |
| Example 15 | Formula 17 | 6.23 (CH, 2H), 2.58 (CH, 2H), 0.94 (CH2, 2H), 1.44 | 69 |
| | | (CH, 2H), 1.75 (CH, 1H), 1.42 (CH, 1H), 2.13 (CH2, | |
| | | 2H), 2.29 (CH, 1H), 2.07 (CH, 1H), 3.46 (CH2, 4H), | |
| | | 2.66 (CH2, 6H), 3.83 (CH2, 6H), 1.21 (CH3, 9H), 11.0 | |
| | | (OH, 1H) | |
| Example 16 | Formula 18 | 5.38 (CH, 1H), 1.82 (CH3, 3H), 2.58 (CH, 1H), 2,26 | 71 |
| | | (CH, 1H), 1.75 (CH2, 2H), 1.44 (CH, 2H), 1.75 (CH, | |
| | | 1H), 1.42 (CH, 1H), 2.13 (CH2, 2H), 2.29 (CH, 1H), | |
| | | 2.07 (CH, 1H), 3.46 (CH2, 2H), 2.66 (CH2, 6H), 3.83 | |
| | | (CH2, 6H), 1.21 (CH3, 9H), 11.0 (OH, 1H) | |

### Example 17

### Preparation of Photosensitive Compound (Formula 19)

### 1) Preparation of Norbornene Compound

As depicted in Reaction Scheme 2, 130 g of cyclopentadiene was added dropwise to a reactor containing the same equivalent of maleic anhydride and 1 L of benzene. The mixture was subjected to a Diels-Alder reaction with stirring. The reactor was cooled in a dry ice bath. After completion of the dropwise addition, the temperature of the reaction mixture was allowed to rise to room temperature. The reaction was carried out with stirring at room temperature for 24 h to obtain a norbornene compound (yield 92%). [H-NMR (CDCl3): δ (ppm), 6.23 (CH2, 2H), 3.77 (CH, 2H), 1.75 (CH2, 2H), 3.02 (CH, 2H)]

### 2) Preparation of Photosensitive Compound (Formula 19)

As depicted in Reaction Scheme 2, 0.3 mol (49.25 g) of the norbornene compound obtained in Example 17 and 0.32 mol (46.79 g) of triethylamine were dissolved in 250 ml of THF and 0.32 mol (63.59 g) of 3-chloropropyltrimethoxysilane was added dropwise thereto. The reaction was allowed to proceed at room temperature. After completion of the reaction, THF was removed by distillation under reduced pressure. The reaction mixture was added with water, neutralized with dilute hydrochloric acid, extracted with ethyl acetate, dried over anhydrous MgSO4, and purified by column chromatography to afford the photosensitive compound represented by Formula 19 (yield 73%). [H-NMR (CDCl3): δ (ppm), 6.23 (CH, 2H), 3.46 (CH, 1H), 3.36 (CH, 1H), 1.75 (CH2, 2H), 2.63 (CH, 1H), 2.72 (CH, 1H), 2.5 (CH2, 2H), 0.86 (CH2, 4H), 3.55 (CH3, 9H), 11.0 (OH, 1H)]

### Examples 18-32

The photosensitive resins represented by Formulas 20-34 were synthesized in the same manner as in Example 17. The structures of the photosensitive compounds were confirmed via H-NMR. The results are shown in Table 2. The yields of the photosensitive compounds are also shown in Table 2.

TABLE 2

| Example No. | Formula | H-NMR data (CDCl3: δ (ppm)) | Yield (%) |
|---|---|---|---|
| Example 18 | Formula 20 | 5.38 (CH, 2H), 1.82 (CH3, 3H), 3.46 (CH, 1H), 2.49 (CH, | 79 |
| | | 1H), 1,75 (CH2, 2H), 2.63 (CH, 1H), 2,72 (CH, 1H), 2.5 | |
| | | (CH2, 2H), 0.86 (CH2, 4H), 3.55 (CH3, 9H), 11.0 (OH, | |
| | | 1H)] | |
| Example 19 | Formula 21 | 6.23 (CH, 2H), 3.46 (CH, 1H), 3.36 (CH, 1H), 1,75 (CH2, | 67 |
| | | 2H), 2.63 (CH, 1H), 2,72 (CH, 1H), 2.5 (CH2, 2H), 0.86 | |
| | | (CH2, 4H), 3.83 (CH2, 6H), 1.21 (CH3, 9H), 11.0 (OH, | |
| | | 1H)] | |
| Example 20 | Formula 22 | 5.38 (CH, 2H), 1.82 (CH3, 3H), 3.46 (CH, 1H), 2.49 (CH, | 74 |
| | | 1H), 1,75 (CH2, 2H), 2.63 (CH, 1H), 2,72 (CH, 1H), 2.5 | |
| | | (CH2, 2H), 0.86 (CH2, 4H), 3.83 (CH2, 6H), 1.21 (CH3, | |
| | | 9H), 11.0 (OH, 1H)] | |
| Example 21 | Formula 23 | 6.23 (CH, 2H), 2.58 (CH, 2H), 0.94 (CH2, 2H), 1.44 (CH, | 70 |
| | | 2H), 1.75 (CH, 1H), 1.65 (CH, 1H), 2.13 (CH2, 2H), 2.52 | |
| | | (CH, 1H), 2.61 (CH, 1H), 2.5 (CH2, 2H), 0.86 (CH2, 4H), | |
| | | 3.55 (CH3, 9H), 11.0 (OH, 1H)] | |
| Example 22 | Formula 24 | 5.38 (CH, 2H), 1.82 (CH3, 3H), 2.58 (CH, 1H), 2.26 (CH, | 77 |
| | | 1H), 1.75 (CH2, 2H), 1.44 (CH, 2H), 1.75 (CH, 1H), 1.65 | |
| | | (CH, 1H), 2.13 (CH2, 2H), 2.52 (CH, 1H), 2.61 (CH, 1H), | |
| | | 2.5 (CH2, 2H), 0.86 (CH2, 4H), 3.55 (CH3, 9H), 11.0 | |
| | | (OH, 1H)] | |
| Example 23 | Formula 25 | 6.23 (CH, 2H), 2.58 (CH, 2H), 0.94 (CH2, 2H), 1.44 (CH, | 75 |
| | | 2H), 1.75 (CH, 1H), 1.65 (CH, 1H), 2.13 (CH2, 2H), 2.52 | |
| | | (CH, 1H), 2.61 (CH, 1H), 2.5 (CH2, 2H), 0.86 (CH2, 4H), | |
| | | 3.83 (CH2, 6H), 1.21 (CH3, 9H), 11.0 (OH, 1H)] | |
| Example 24 | Formula 26 | 5.38 (CH, 2H), 1.82 (CH3, 3H), 2.58 (CH, 1H), 2.26 (CH, | 64 |
| | | 1H), 1.75 (CH2, 2H), 1.44 (CH, 2H), 1.75 (CH, 1H), 1.65 | |
| | | (CH, 1H), 2.13 (CH2, 2H), 2.52 (CH, 1H), 2.61 (CH, 1H), | |
| | | 2.5 (CH2, 2H), 0.86 (CH2, 4H), 3.83 (CH2, 6H), 1.21 | |
| | | (CH3, 9H), 11.0 (OH, 1H)] | |
| Example 25 | Formula 27 | 6.23 (CH, 2H), 3.46 (CH, 1H), 3.36 (CH, 1H), 1,75 (CH2, | 71 |
| | | 2H), 2.63 (CH, 1H), 2.80 (CH, 1H), 8.03 (NH, 1H), 2.49 | |
| | | (CH2, 6H), 3.55 (CH3, 9H), 11.0 (OH, 1H) | |
| Example 26 | Formula 28 | 5.38 (CH, 1H), 1.82 (CH3, 3H), 3.46 (CH, 1H), 2.49 (CH, | 74 |
| | | 1H), 1,75 (CH2, 2H), 2.63 (CH, 1H), 2.80 (CH, 1H), 8.03 | |
| | | (NH, 1H), 2.49 (CH2, 6H), 3.55 (CH3, 9H), 11.0 (OH, | |
| | | 1H) | |
| Example 27 | Formula 29 | 6.23 (CH, 2H), 3.46 (CH, 1H), 3.36 (CH, 1H), 1,75 (CH2, | 72 |
| | | 2H), 2.63 (CH, 1H), 2.80 (CH, 1H), 8.03 (NH, 1H), 2.49 | |
| | | (CH2, 6H), 3.83 (CH2, 6H), 1.21 (CH3, 9H), 11.0 (OH, | |
| | | 1H) | |
| Example 28 | Formula 30 | 5.38 (CH, 1H), 1.82 (CH3, 3H), 3.46 (CH, 1H), 2.49 (CH, | 72 |
| | | 1H), 1,75 (CH2, 2H), 2.63 (CH, 1H), 2.80 (CH, 1H), 8.03 | |
| | | (NH, 1H), 2.49 (CH2, 6H), 3.83 (CH2, 6H), 1.21 (CH3, | |
| | | 9H), 11.0 (OH, 1H) | |
| Example 29 | Formula 31 | 6.23 (CH, 2H), 2.58 (CH, 2H), 0.94 (CH2, 2H), 1.44 (CH, | 73 |
| | | 2H), 1.75 (CH60 8.03 (NH, 1H), 2.49 (CH2, 6H), 3.55 | |
| | | (CH3, 9H), 11.0 (OH, 1H) | |
| Example 30 | Formula 32 | 5.38 (CH, 1H), 1.82 (CH3, 3H), 2.58 (CH, 1H), 2.26 (CH, | 70 |
| | | 1H), 1.75 (CH2, 2H), 1.44 (CH, 2H), 1.75 (CH, 1H), 1.65 | |
| | | (CH, 1H), 2.13 (CH2, 2H), 2.52 (CH, 1H), 3.57 (CH, 1H), | |
| | | 8.03 (NH, 1H), 2.49 (CH2, 6H), 3.55 (CH3, 9H), 11.0 | |
| | | (OH, 1H) | |
| Example 31 | Formula 33 | 6.23 (CH, 2H), 2.58 (CH, 2H), 0.94 (CH2, 2H), 1.44 (CH, | 65 |
| | | 2H), 1.75 (CH64 2.52 (CH, 1H), 3.57 (CH, 1H). 8.03 (NH, | |
| | | 1H), 2.49 (CH2, 6H), 3.83 (CH2, 6H), 1.21 (CH3, 9H), | |
| | | 11.0 (OH, 1H) | |
| Example 32 | Formula 34 | 5.38 (CH, 1H), 1.82 (CH3, 3H), 2.58 (CH, 1H), 2.26 (CH, | 63 |
| | | 1H), 1.75 (CH2, 2H), 1.44 (CH, 2H), 1.75 (CH, 1H), 1.65 | |
| | | (CH, 1H), 2.13 (CH2, 2H), 2.52 (CH, 1H), 3.57 (CH, 1H), | |
| | | 8.03 (NH, 1H), 2.49 (CH2, 6H), 3.83 (CH2, 6H), 1.21 | |
| | | (CH3, 9H), 11.0 (OH, 1H) | |

### Example 33

### Preparation of Photosensitive Polymer Resin

62.57 g (0.198 mol) of the photosensitive compound represented by Formula 3, 75.45 g (0.322 mol) of 2-methyl-2-adamantyl methacrylate, 46.79 g (0.198 mol) of hydroxyadamantyl methacrylate, and 12 g of azobis(isobutyronitrile) (AIBN) were dissolved in 120 g of anhydrous THF. The reaction mixture was degassed by freezing in an ampoule, followed by polymerization at 66° C. for 12 h. The polymerization mixture was dropped into an excess of diethyl ether slowly. The resulting precipitate was dissolved in THF and reprecipitated in diethyl ether to obtain a photosensitive polymer resin (Mn=4739, Mw=8531, PDI=1.80 as analyzed by GPC).

### Example 34

### Preparation of Photosensitive Polymer Resin

A photosensitive polymer resin was obtained in the same manner as in Example 33, except that 65.34 g (0.198 mol) of the photosensitive compound represented by Formula 7 was used (Mn=4701, Mw=8312, PDI=1.77 as analyzed by GPC).

### Example 35

### Preparation of Photosensitive Polymer Resin

A photosensitive polymer resin was obtained in the same manner as in Example 33, except that 75.64 g (0.198 mol) of the photosensitive compound represented by Formula 11 was used (Mn=4715, Mw=8632, PDI=1.83 as analyzed by GPC).

### Example 36

### Preparation of Photosensitive Polymer Resin

A photosensitive polymer resin was obtained in the same manner as in Example 33, except that 78.41 g (0.198 mol) of the photosensitive compound represented by Formula 15 was used (Mn=4551, Mw=7345, PDI=1.65 as analyzed by GPC).

### Example 37

### Preparation of Photosensitive Polymer Resin

A photosensitive polymer resin was obtained in the same manner as in Example 33, except that 62.17 g (0.198 mol) of the photosensitive compound represented by Formula 19 was used (Mn=4571, Mw=8332, PDI=1.82 as analyzed by GPC).

### Example 38

### Preparation of Photosensitive Polymer Resin

A photosensitive polymer resin was obtained in the same manner as in Example 33, except that 75.24 g (0.198 mol) of the photosensitive compound represented by Formula 23 was used (Mn=3857, Mw=7243, PDI=1.88 as analyzed by GPC).

### Example 39

### Preparation of Photosensitive Polymer Resin

A photosensitive polymer resin was obtained in the same manner as in Example 33, except that 62.14 g (0.198 mol) of the photosensitive compound represented by Formula 27 was used (Mn=4957, Mw=9112, PDI=1.84 as analyzed by GPC).

### Example 40

### Preparation of Photosensitive Polymer Resin

A photosensitive polymer resin was obtained in the same manner as in Example 33, except that 78.21 g (0.198 mol) of the photosensitive compound represented by Formula 31 was used (Mn=4832, Mw=8453, PDI=1.75 as analyzed by GPC).

### Examples 41-48

### Preparation of Chemically Amplified Photoresist Compositions

2 g of each of the photosensitive polymer resins obtained in Examples 33-40 and 0.02 g of triphenylsulfonium triflate were completely dissolved in 20 g of propylene glycol monomethyl ether acetate (PGMEA). Then, the solution was filtered through a 0.2 m disk filter to obtain a chemically amplified photoresist composition. The photoresist composition was coated to a thickness of ˜0.2 m on a silicon wafer treated with hexamethyldisilazane. The wafer coated with the photoresist composition was prebaked at 120° C. for 90 sec, exposed to an ArF excimer laser with a numerical aperture of 0.60, heated at 120° C. for 90 sec (PEB), and developed with a 2.38 wt % tetramethylammonium hydroxide (TMAH) solution for 30 sec to obtain a photoresist pattern with equal lines and spaces (0.1 m).

### Comparative Example 1

A chemically amplified photoresist composition was prepared in the same manner as in Example 41, except that a conventional photosensitive polymer resin prepared from 2-methyl-2-adamantyl methacrylate and y-butyrolactone methacrylate (Mn=5105, Mw=9874, PDI=1.93 as analyzed by GPC) was used instead of the photosensitive resin obtained in Example 33.

### Experimental Example 1

The weight average molecular weight (Mw), number average molecular weight (Mn), and degree of dispersion (PDI) of each of the polymer resins used in Examples 41-48 and Comparative Example 1 were measured. The LER (unit, mm) and etching resistance of the pattern formed using each of the resist compositions prepared in Examples 41-48 and Comparative Example 1 were also measured.

For LER and etching resistance measurements, each of the resist compositions prepared in Examples 41-48 and Comparative Example 1 was coated on a wafer, prebaked at 130° C. for 90 sec, exposed to an ArF excimer laser with a numerical aperture of 0.60, baked at 130° C. for 90 sec (post-exposure bake (PEB)), and developed with a 2.38 wt % tetramethylammonium hydroxide (TMAH) solution for 30 sec to obtain a pattern with 1:1 lines and spaces (0.14 μm). The LER and etching resistance of the pattern were measured. The results are shown in Table 3.

TABLE 3

| Example No. | Mw | Mn | PDI | LER | Etching resistance |
|---|---|---|---|---|---|
| Example 41 | 8531 | 4739 | 1.80 | 5.1 | 1.35 |
| Example 42 | 8312 | 4701 | 1.77 | 4.9 | 1.30 |
| Example 43 | 8632 | 4715 | 1.83 | 4.7 | 1.43 |
| Example 44 | 7345 | 4551 | 1.65 | 3.9 | 1.39 |
| Example 45 | 8332 | 4571 | 1.82 | 4.6 | 1.28 |
| Example 46 | 7243 | 3857 | 1.88 | 5.2 | 1.25 |
| Example 47 | 9112 | 4957 | 1.84 | 4.8 | 1.18 |
| Example 48 | 8453 | 4832 | 1.75 | 4.3 | 1.15 |
| Comparative | 9874 | 5105 | 1.93 | 9.5 | 1.00 |
| Example 1 | | | | | |

As can be seen from the results in Table 3, the presence of silicon in the inventive photosensitive resins and the introduction of norbornene moieties, which are bulky alicyclic hydrocarbons, into the inventive photosensitive resins led to enhanced etching resistance. The increased etching resistance leads to enhanced heat resistance and improved adhesion to semiconductor circuit boards. In addition, the structure of each of the inventive photosensitive resins in which organic acid groups are present in silicon-containing norbornene moieties, which are bulky alicyclic hydrocarbons, was confirmed to facilitate control over the solubility of the photosensitive resin and increase the contrast due to the difference in solubility, leading to a low line edge roughness (LER).

Although the particulars of the present invention have been described in detail, it will be obvious to those skilled in the art that such particulars are merely preferred embodiments and are not intended to limit the scope of the present invention. Therefore, the true scope of the present invention is defined by the appended claims and their equivalents.

1. A photosensitive compound having a structure represented by Formula 1 or 2: 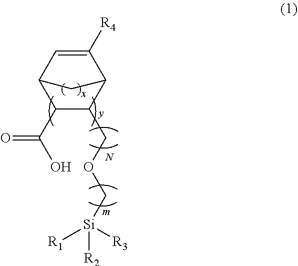
wherein x is 0 or 1, y is an integer from 0 to 3, z is an integer from 1 to 10, m is an integer from 1 to 6, R₁, R₂, and R₃ are each independently a C₁-C₁₀ hydrocarbon or OCₙH₂ₙ₊₁ (n is an integer from 0 to 10), and R₄ is H or CH₃; 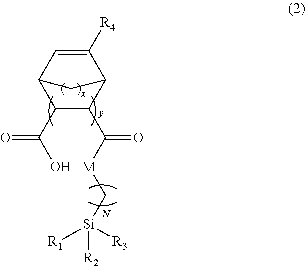
wherein x is 0 or 1, y is an integer from 0 to 3, z is an integer from 1 to 10, M is C, O, N or S, R₁, R₂, and R₃ are each independently a C₁-C₁₀ hydrocarbon or OCₙH₂ₙ₊₁ (n is an integer from 1 to 10), and R₄ is H or CH₃.

2. The photosensitive compound according to claim 1, wherein the photosensitive compound is selected from the group consisting of the compounds represented by Formulas 3 to 34:

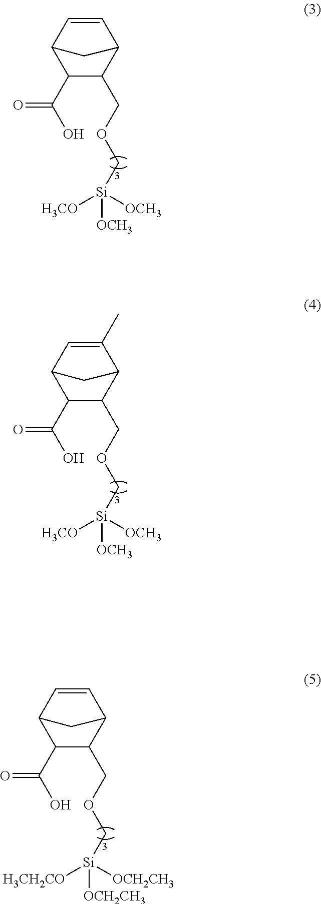

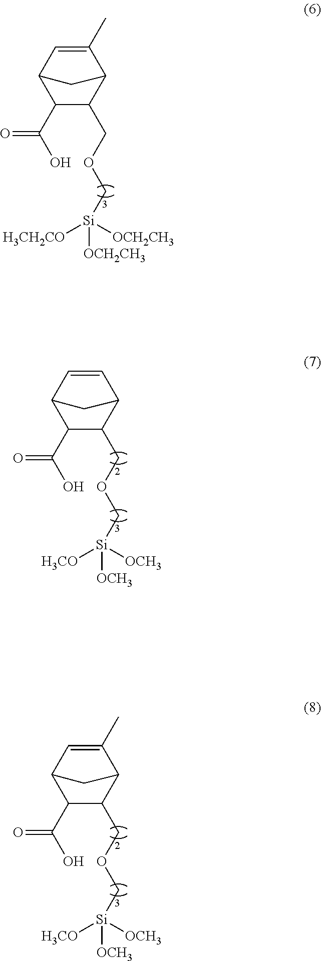

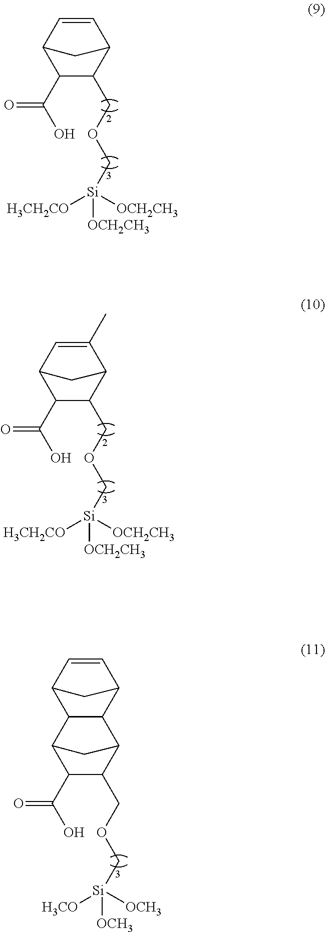

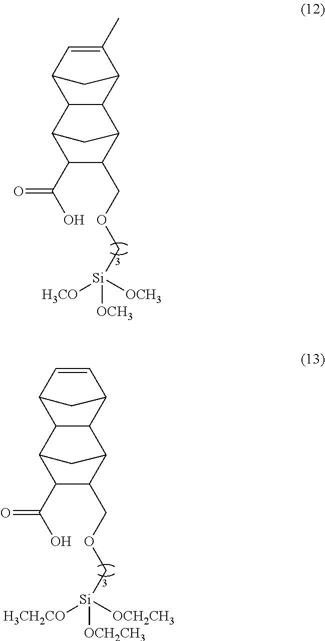

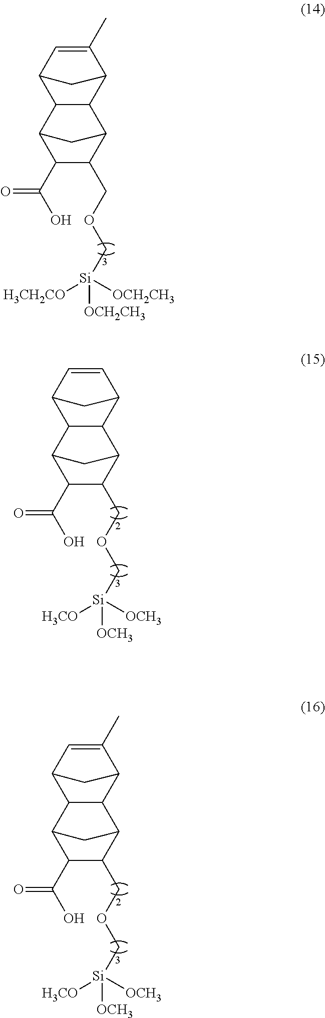

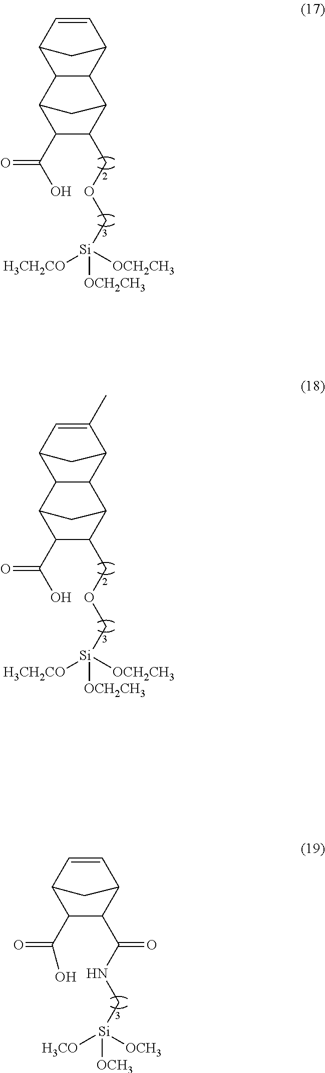

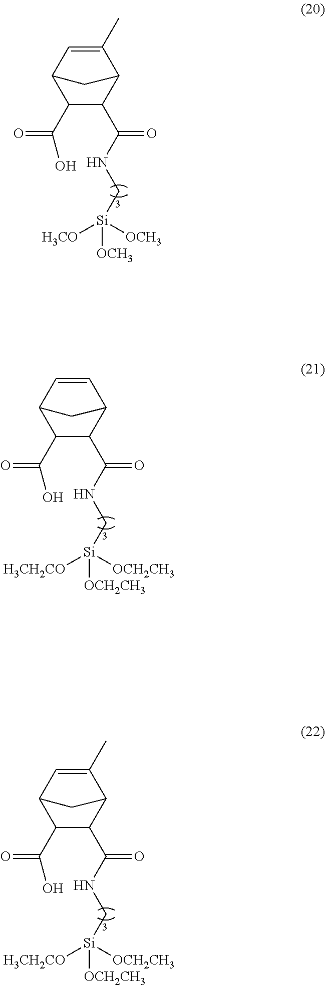

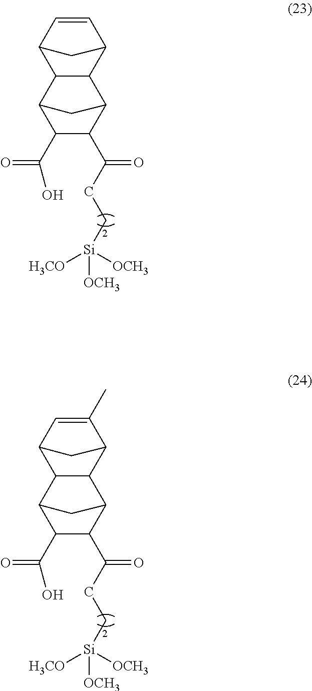

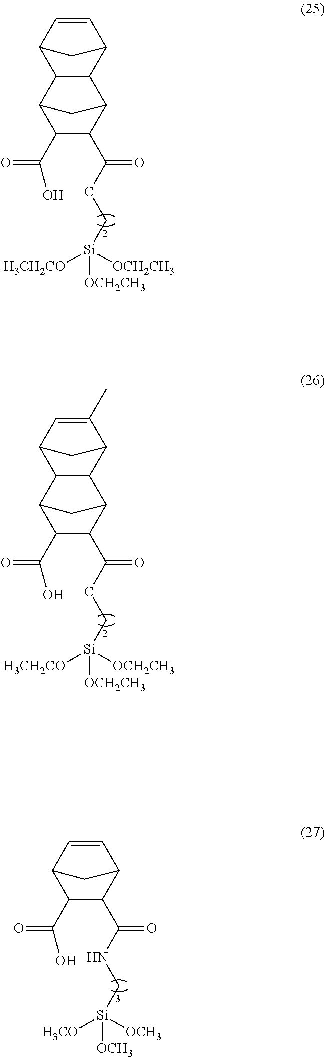

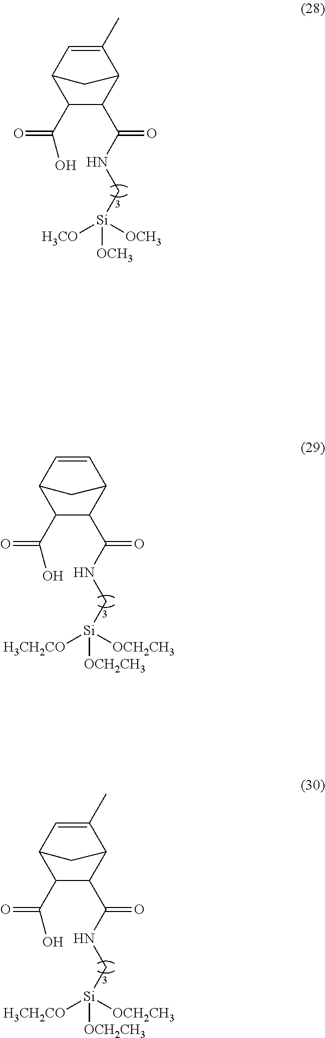

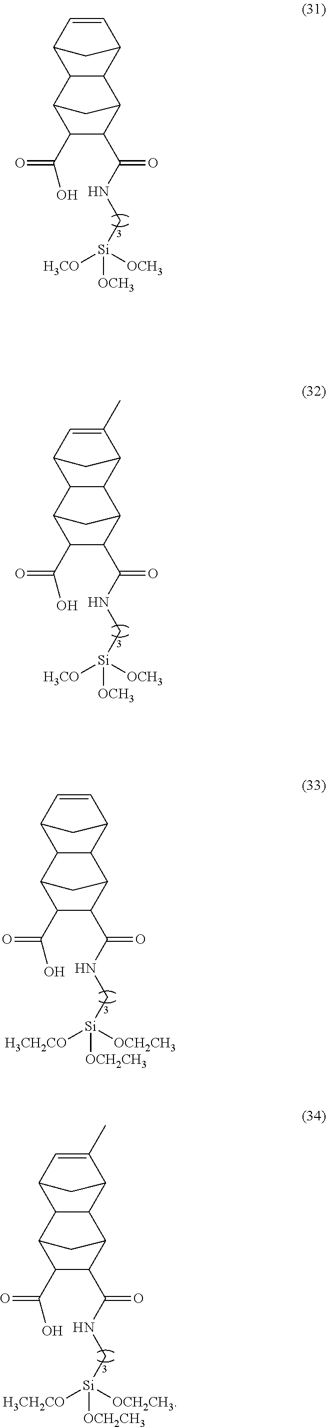

3. A photosensitive resin having a structure represented by Formula 35 or 36: 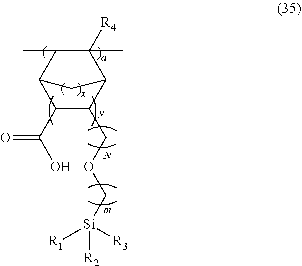
wherein x is 0 or 1, y is an integer from 0 to 3, z is an integer from 1 to 10, m is an integer from 1 to 6, R₁, R₂, and R₃ are each independently a C₁-C₁₀ hydrocarbon or OCₙH₂ₙ₊₁ (n is an integer from 0 to 10), R₄ is H or CH₃, and a represents the mole fraction of the repeating unit having the structure represented by Formula 35 in all repeating units of the photosensitive resin and is 0.01 to 100 mol %, 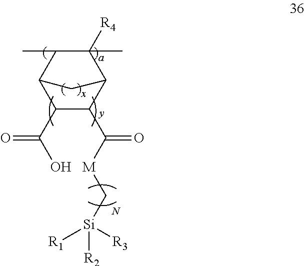
wherein x is 0 or 1, y is an integer from 0 to 3, z is an integer from 1 to 10, M is C, O, N or S, R₁, R₂, and R₃ are each independently a C₁-C₁₀ hydrocarbon or OCₙH₂ₙ₊₁ (n is an integer from 1 to 10), R₄ is H or CH₃, and a represents the mole fraction of the repeating unit having the structure represented by Formula 36 in all repeating units of the photosensitive resin and is 0.01 to 100 mol %.

4. The photosensitive resin according to claim 3, wherein the photosensitive resin comprises a structure represented by Formula 37 or 38: 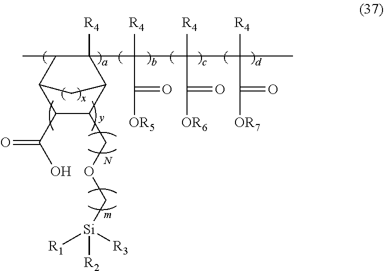
wherein each R₄ is independently H or a C₁-C₆ alkyl group, R₁, R₂, and R₃ are each independently a C₁-C₁₀ hydrocarbon or OCₙH₂ₙ₊₁ (n is an integer from 1 to 10), R₅ is a C₁-C₂₀ alkyl group or a C₅-C₄₀ cycloalkyl group, R₆ and R₇ are each independently a C₁-C₂₀ hydroxyalkyl group, a C₁-C₁₀ halogenated hydroxyalkyl group or a C₅-C₁₀ cycloalkyl group containing an ether or ester moiety, and a, b, c, and d represent the mole fractions of the corresponding repeating units in all photosensitive compounds of the photosensitive polymer resin and are in a ratio of 1-70:1-50:1-50:1-50; 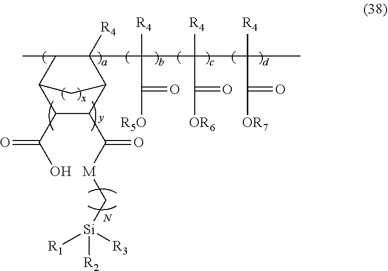
wherein R₁, R₂, R₃, R₄, R₅, R₆, R₇, a, b, c, and d are as defined in Formula 37.

5. The photosensitive resin according to claim 3, wherein a is 1 to 70 mol %.

6. The photosensitive resin according to claim 3, wherein the photosensitive resin has a weight average molecular weight of 1,000 to 100,000.

7. A photoresist composition comprising a photosensitive resin having a structure represented by Formula 35 or 36, a photoacid generator, and an organic solvent: 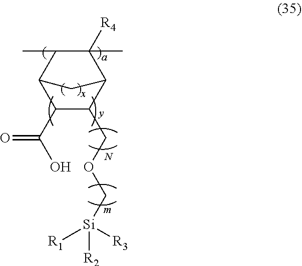
wherein x is 0 or 1, y is an integer from 0 to 3, z is an integer from 1 to 10, m is an integer from 1 to 6, R₁, R₂, and R₃ are each independently a C₁-C₁₀ hydrocarbon or OCₙH₂ₙ₊₁ (n is an integer from 0 to 10), R₄ is H or CH₃, and a represents the mole fraction of the repeating unit having the structure represented by Formula 35 in all repeating units of the photosensitive resin and is 0.01 to 100 mol %, 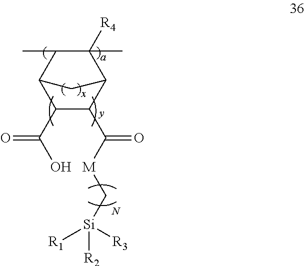
wherein x is 0 or 1, y is an integer from 0 to 3, z is an integer from 1 to 10, M is C, O, N or S, R₁, R₂, and R₃ are each independently a C₁-C₁₀ hydrocarbon or OCₙH₂ₙ₊₁1 (n is an integer from 1 to 10), R₄ is H or CH₃, and a represents the mole fraction of the repeating unit having the structure represented by Formula 36 in all repeating units of the photosensitive resin and is 0.01 to 100 mol %.

8. The photoresist composition according to claim 7, wherein the photosensitive resin is present in an amount of 1 to 30% by weight, based on the total weight of the photoresist composition.

9. The photoresist composition according to claim 7, wherein the photoacid generator is selected from organic sulfonic acids, sulfide salt compounds, onium salt compounds, and mixtures thereof and is present in an amount of 0.1 to 20 parts by weight, based on 100 parts by weight of the photosensitive resin.

10. The photoresist composition according to claim 7, wherein the organic solvent is selected from the group consisting of ethylene glycol monomethyl ethyl, ethylene glycol monoethyl ether, ethylene glycol monomethyl ether, diethylene glycol monoethyl ether, propylene glycol monomethyl ether acetate, toluene, xylene, methyl ethyl ketone, cyclohexanone, 2-hydroxyethyl propionate, 2-hydroxy-2-methyl ethyl propionate, ethoxyethyl acetate, hydroxyethyl acetate, 2-hydroxy-3-methyl methyl butanoate, 3-methoxy-2-methyl methyl propionate, 3-ethoxyethyl propionate, 3-methoxy-2-methyl ethyl propionate, ethyl acetate, butyl acetate, and mixtures thereof.
